(19) United States
(12) Patent Application Publication
(10) Pub. No.: US 2022/0115227 A1
(43) Pub. Date: Apr. 14, 2022

(54) SEMICONDUCTOR STRUCTURE PREPARATION PROCESS AND SEMICONDUCTOR STRUCTURE

(71) Applicant: CHANGXIN MEMORY TECHNOLOGIES, INC., Hefei City (CN)

(72) Inventor: Junjie XU, Hefei City (CN)

(21) Appl. No.: 17/487,779

(22) Filed: Sep. 28, 2021

Related U.S. Application Data
(63) Continuation of application No. PCT/CN2021/107135, filed on Jul. 19, 2021.

(30) Foreign Application Priority Data
Oct. 14, 2020 (CN) 202011097098.9

(51) Int. Cl. H01L 21/02; H01L 23/48; H01L 21/768; C23C 16/34; C23C 16/455; C23C 16/52

(52) U.S. Cl. CPC H01L 21/0217; H01L 23/481; H01L 21/76898; H01L 21/76832; H01L 21/0228; C23C 16/52; H01L 21/76834; H01L 21/76826; C23C 16/345; C23C 16/45536; H01L 21/02274

(57) ABSTRACT

The present disclosure provides a semiconductor structure preparation process and a semiconductor structure. The preparation process includes the following steps of: introducing a first silicon source, and forming a first silicon containing material layer by deposition on the surface of a base of a semiconductor structure; introducing a first nitrogen source, and forming a first nitrided material layer by deposition on the surface of the first silicon containing material layer using a chemical vapor deposition process; introducing a second silicon source, and forming a second silicon containing material layer by deposition on the surface of the first nitrided material layer; and introducing a second nitrogen source, and forming a second nitrided material layer by deposition on the surface of the second silicon containing material layer using a plasma deposition process. According to the present disclosure, the prepared semiconductor structure has excellent film resistance uniformity and higher product yields.

### CROSS-REFERENCE TO RELATED APPLICATIONS

This application is a continuation application of International Patent Application No. PCT/CN2021/107135, filed on Jul. 19, 2021, which claims priority to Chinese Patent Application No. 202011097098.9, filed with the Chinese Patent Office on Oct. 14, 2020 and entitled “SEMICONDUCTOR STRUCTURE PREPARATION PROCESS AND SEMICONDUCTOR STRUCTURE.” International Patent Application No. PCT/CN2021/107135 and Chinese Patent Application No. 202011097098.9 are incorporated herein by reference in their entireties.

### TECHNICAL FIELD

The present disclosure relates to the field of semiconductor structure technologies, and in particular to a semiconductor structure preparation process and a semiconductor structure.

### BACKGROUND

At present, in the existing process that deposition of a nitride layer of a semiconductor structure is achieved using a deposition apparatus such as a deposition furnace tube, a concentration of a nitrogen source (e.g., ammonia gas, NH3) at the bottom of the furnace tube is relatively high due to the machine characteristics of the furnace tube. In addition, a plasma deposition process is typically employed in the existing process to achieve deposition of the nitride layer (e.g., silicon nitride, SiN), so during the above deposition process, the activity of the ammonia gas is further improved by plasmas. This causes a surface of a conductive layer (e.g., tungsten, W) of a base of a semiconductor product, especially the semiconductor product at the bottom of the furnace tube, to be more susceptible to nitridation, thereby increasing the resistance of the semiconductor product and resulting in poor film resistance uniformity.

### SUMMARY

Embodiments of the present disclosure is to overcome at least one shortcoming in the above prior art, and to provide a semiconductor structure preparation process that can prevent a conductive layer from being nitrided during the process.

According to an aspect of the present disclosure, a semiconductor structure preparation process is provided, wherein the semiconductor structure preparation process includes the following steps of:

introducing a first silicon source, and forming a first silicon containing material layer by deposition on a surface of a base of a semiconductor structure;

introducing a first nitrogen source, and forming a first nitrided material layer by deposition on a surface of the first silicon containing material layer using a chemical vapor deposition process;

introducing a second silicon source, and forming a second silicon containing material layer by deposition on a surface of the first nitrided material layer; and

introducing a second nitrogen source, and forming a second nitrided material layer by deposition on a surface of the second silicon containing material layer using a plasma deposition process.

According to another aspect of the present disclosure, a semiconductor structure is provided, wherein the semiconductor structure includes a base, a metal material layer is arranged on the surface of the base, a first nitrided material layer and a second nitrided material layer are sequentially arranged on the surface of the metal material layer, the first nitrided material layer is formed through a chemical vapor deposition process, and the second nitrided material layer is formed through a plasma deposition process.

### BRIEF DESCRIPTION OF DRAWINGS

Various objects, features, and advantages of the present disclosure will become more apparent when considering the following detailed description of the exemplary implementations of the present disclosure in conjunction with the accompanying drawings. The drawings are merely exemplary illustrations of the present disclosure, and are not necessarily drawn to scale. In the drawings, like reference numerals always indicate like or similar components, wherein:

FIG. 1 is a schematic diagram of a semiconductor structure in a step of a semiconductor structure preparation process shown in accordance with an exemplary implementation;

FIG. 2 is a schematic diagram of a semiconductor structure in another step of a semiconductor structure preparation process shown in accordance with an exemplary implementation;

FIG. 3 is a schematic diagram of a semiconductor structure in another step of a semiconductor structure preparation process shown in accordance with an exemplary implementation; and

FIG. 4 is a schematic diagram of a semiconductor structure in another step of a semiconductor structure preparation process shown in accordance with an exemplary implementation.

### REFERENCE NUMERALS

100 base;
110 substrate;
120 conductive layer;
130 first silicon-containing material layer;
141 first nitrided material layer;
142 second nitrided material layer;
210 first silicon source;
220 first nitrogen source.

### DESCRIPTION OF EMBODIMENTS

Typical embodiments embodying the features and advantages of the present disclosure will be described in detail in the following description. It will be appreciated that the present disclosure can have, on different embodiments, various changes which do not depart from the scope of the present disclosure, and the description and drawings therein are in nature for illustrative purposes, rather than limiting the present disclosure.

The following description of different exemplary implementations of the present disclosure is made with reference to the accompanying drawings, which constitute a part of the present disclosure, and different exemplary structures, systems and steps of a plurality of aspects of the present disclosure are shown by way of example. It is to be understood that other particular solutions for components, structures, exemplary devices, systems, and steps may be used, and structural and functional modifications may be made without departing from the scope of the present disclosure. Moreover, although terms “above”, “between”, “within”, etc. may be used in this specification to describe different exemplary features and elements of the present disclosure, these terms are used herein for convenience only, e.g., directions according to the examples described in the drawings. No content in this specification shall be understood as requiring a specific three-dimensional direction of the structure to fall within the scope of the present disclosure.

Reference is made to FIG. 1 to FIG. 4, which, respectively, representatively illustrate the schematic diagrams of a semiconductor structure in several steps of the semiconductor structure preparation process according to the present disclosure. In this exemplary implementation, the semiconductor structure preparation process according to the present disclosure is described with reference to an example that a nitride is deposited on the surface of a semiconductor structure by utilizing a deposition furnace tube. Those skilled in the art would readily understand that in order to apply the relevant design of the present disclosure to other types of processes, various modifications, additions, substitutions, deletions or other changes are made to the following specific implementations. These changes are still within the scope of the principle of the semiconductor structure preparation process according to the present disclosure.

As shown in FIG. 1 to FIG. 4, in some embodiments, the semiconductor structure preparation process according to the present disclosure includes the following steps of:

introducing a first silicon source 210, and forming a first silicon containing material layer 130 by deposition on the surface of a base 100 of a semiconductor structure;

introducing a first nitrogen source 220, and forming a first nitrided material layer 141 by deposition on the surface of the first silicon containing material layer 130 using a chemical vapor deposition process;

introducing a second silicon source, and forming a second silicon containing material layer by deposition on the surface of the first nitrided material layer 141; and

introducing a second nitrogen source, and forming a second nitrided material layer 142 by deposition on the surface of the second silicon containing material layer using a plasma deposition process.

In conclusion, in the semiconductor structure preparation process according to the embodiments of the present disclosure, such a process design is employed that a nitride is deposited on the surface of a conductive layer 120 using the chemical vapor deposition process and then deposited using the plasma deposition process. Nitrogen sources are not affected by plasmas during the chemical vapor deposition process and their activities are thus improved, as a result of which the conductive layer 120 exposed can be prevented from being nitrided. Furthermore, according to the embodiments of the present disclosure, the first silicon containing material layer 130 is formed by deposition on the surface of the conductive layer 120 of the base 100 of the semiconductor structure before the nitride is deposited, thereby preventing the conductive layer 120 from being nitrided during the subsequent nitride deposition process.

It is to be noted that the first nitrogen source 220 and the second nitrogen source described hereinabove are both nitrogen gas (NH₃). Experiments have verified that during the chemical vapor deposition (e.g., thermal chemical vapor deposition) process, the nitrogen source of this type is characterized by a low resistance state, and there is no phenomenon that the uniformity of the product at the bottom is poor due to the furnace tube. Accordingly, in the embodiments of the present disclosure, the chemical vapor deposition process is employed without turning on the plasmas when deposition of the nitride begins, and during the subsequent nitride deposition process, the plasma deposition process is utilized while the plasmas are turned on, thus effectively preventing the exposed conductive layer 120 from being nitrided. In addition, the conductive layer 120 is partly exposed to the substrate 110 before the nitride is not deposited, so according to the embodiments of the present disclosure, the first silicon source 210 of dichlorosilane is introduced prior to nitride deposition, and the surface of the conductive layer 120 is covered with the first silicon containing material layer 130. By doing so, the nitrogen source in the subsequent nitride deposition process can be prevented in advance from contact with the conductive layer 120, and further oxidation of the conductive layer 120 is avoided.

As shown in FIG. 1, this drawing representatively illustrates the exemplary structure of the semiconductor structure in the above-mentioned step of “forming a first silicon containing material layer 130”. In particular, the base 100 of the semiconductor structure in this step includes the substrate 110 (e.g., silicon substrate, Si) and the conductive layer 120 (e.g., tungsten, W). The conductive layer 120 is located in the substrate 110 and is partly exposed to a hole of the substrate 110. On this basis, the first silicon source 210 introduced is adhered to the surface of the exposed conductive layer 120, so as to form the first silicon containing material layer 130 that covers the surface of the conductive layer 120.

In some embodiments, as for the step of “forming a first silicon containing material layer 130”, the first silicon source 210 may be deposited on the surface of the conductive layer 120 using chemical vapor deposition or other such processes.

In some embodiments, as for the step of “forming a first silicon containing material layer 130”, introduction of the first silicon source 210 may be carried out in multiple cycles. In other implementations, introduction of the first silicon source 210 may also be carried out in one cycle, and is not limited to this implementation.

In some embodiments, based on the process design that introduction of the first silicon source 210 is carried out in multiple cycles, as for the step of “forming a first silicon containing material layer 130”, the number of cycles for introduction of the first silicon source 210 may be 3 to 7, e.g., 3, 5, 6, 7, etc., in this implementation. In other implementations, when introduction of the first silicon source 210 is carried out in multiple cycles, the number of cycles for introduction of the first silicon source 210 may also be less than 3, or more than 7, e.g., 2, 8, etc., and is not limited to this implementation.

In an exemplary embodiment, as for the step of “forming a first silicon containing material layer 130”, the first silicon source 210 may include dichlorosilane (DCS in short, chemical formula: SiH₂Cl₂). In other implementations, other silicon containing compounds may also be used as the first silicon source 210, e.g., trichlorosilane (HCl₃Si) or silane (SiH₄). The first silicon source 210 may also be a composition of at least two of the above silicon containing compounds, and is not limited to this implementation.

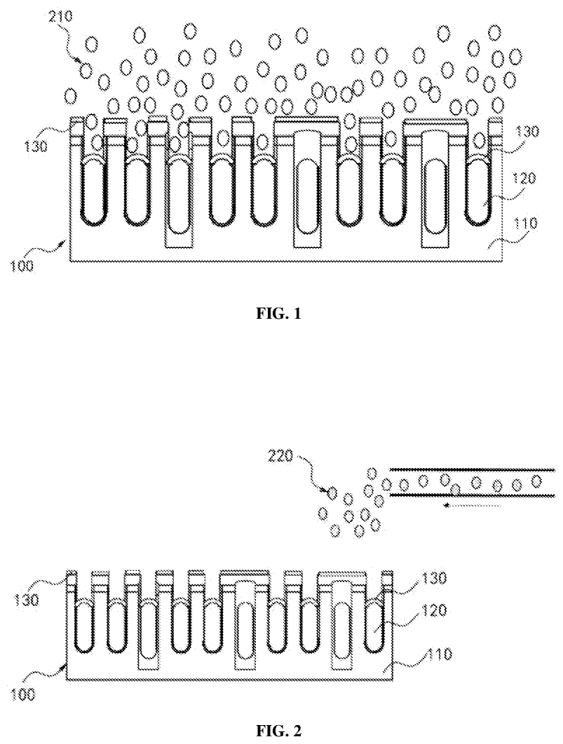

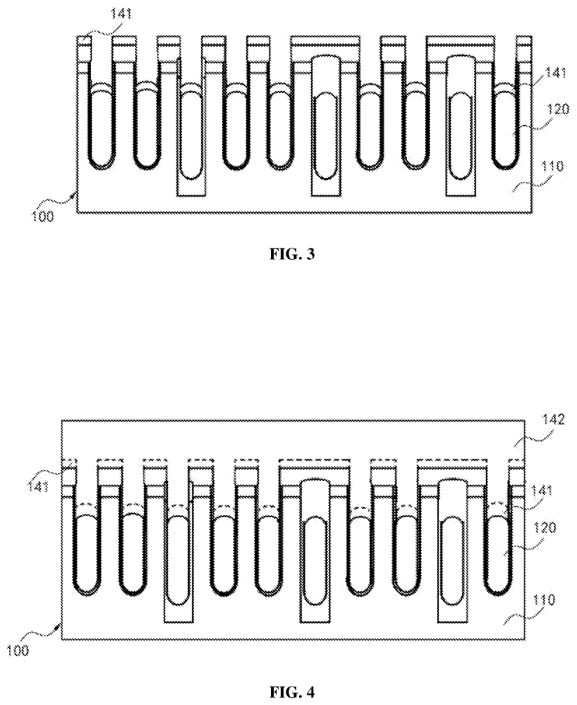

As shown in FIG. 2 and FIG. 3, these drawings representatively illustrate, in the above step of “forming a first nitrided material layer 141”, the exemplary structure of the semiconductor structure when the first nitrogen source 220 is introduced and when the first nitrided material layer 141 is formed. In particular, the semiconductor structure in this step includes the substrate 110, the conductive layer 120, the first silicon containing material layer 130 (not shown in the drawing) and the first nitrided material layer 141. On this basis, the first nitrogen source 220 introduced is deposited on the surface of the exposed conductive layer 120 (covered with the first silicon containing material layer 130) using the chemical vapor deposition process, so as to form the nitrided material layer that covers the surface of the conductive layer 120. To provide its distinction from the hereinafter-described nitrided material layer that is deposited using the plasma deposition process, the nitrided material layer deposited in this step is defined as the first nitrided material layer 141. During the above deposition process, a nitridation reaction that occurs in the exposed conductive layer 120 due to nitride deposition can be further avoided since the surface of the exposed conductive layer 120 is covered with the first silicon containing material layer 130 in advance.

In an exemplary embodiment, as for the step of “forming a first nitrided material layer 141”, the flow rate for introduction of the first nitrogen source 220 may be 10 slm to 30 slm, e.g., 10 slm, 15 slm, 25 slm, 30 slm, etc. In other implementations, the flow rate for introduction of the first nitrogen source 220 may also be less than 10 slm, or more than 30 slm, e.g., 8 slm, 31 slm, etc., and is not limited to this implementation. With the above design, the embodiments of the present disclosure can decrease, for example, the amount of the nitrogen source for ammonia gas and further prevent the conductive layer 120 from being oxidized, when compared to the solution in the existing process that the flow rate of the nitrogen source is generally about 45 slm.

In some embodiments, based on the process design that the flow rate for introduction of the first nitrogen source 220 is 10 slm to 30 slm, the flow rate for introduction of the first nitrogen source 220 in this implementation may be 24 slm.

In an exemplary embodiment, as for the step of “forming a first nitrided material layer 141”, the first nitrogen source 220 may include ammonia gas (NH₃). In other implementations, other nitrogen element-containing compounds may also be used, e.g., nitrogen-containing gases, etc. The alternative ammonia gas is used as the first nitrogen source 220, which is not limited to this implementation.

In an exemplary embodiment, as for the step of “forming a first nitrided material layer 141”, the thickness at which the first nitrided material layer 141 is deposited may be 3 nm to 15 nm, e.g., 3 nm, 11 nm, 14 nm, 15 nm, etc. In other implementations, the thickness at which the first nitrided material layer 141 is deposited may also be more than 15 nm, e.g., 16 nm, etc., and is not limited to this implementation.

As shown in FIG. 3, in some embodiments, as for the step of “forming a first nitrided material layer 141” and as for a portion of the first nitrided material layer 141 that is located in a groove of the substrate 110, the thickness of deposition may be 3 nm to 10 nm.

In an exemplary embodiment, as for the step of “forming a first nitrided material layer 141”, the second silicon source may be deposited on the surface of the first nitrided material layer 141 using chemical vapor deposition or other such processes.

In an exemplary embodiment, as for the step of “forming a first nitrided material layer 141”, the second silicon source may include dichlorosilane. In other implementations, other silicon containing compounds may also be used as the second silicon source, e.g., trichlorosilane or silane. The second silicon source may also be a composition of at least two of the above silicon containing compounds, and is not limited to this implementation.

As shown in FIG. 4, this drawing representatively illustrates the exemplary structure of the semiconductor structure in the above step of “forming a second nitrided material layer 142”. In particular, the semiconductor structure in this step includes the substrate 110, the conductive layer 120, the first silicon containing material layer 130, the first nitrided material layer 141 and the second silicon containing material layer (not shown in the drawing). On this basis, the second nitrogen source introduced is deposited on the surface of the exposed conductive layer 120 (deposited sequentially with the first silicon containing material layer 130, the first nitrided material layer 141 and the second silicon containing material layer) using the plasma deposition process, so as to form the nitrided material layer that covers the surface of the conductive layer 120. To provide its distinction from the above-mentioned nitrided material layer that is deposited using the chemical vapor deposition process, the nitrided material layer deposited in this step is defined as the second nitrided material layer 142.

In an exemplary embodiment, as for the step of “forming a second nitrided material layer 142”, the flow rate for introduction of the second nitrogen source may be 20 slm to 50 slm, e.g., 20 slm, 25 slm, 40 slm, 50 slm, etc. In other implementations, the flow rate for introduction of the second nitrogen source may also be less than 20 slm, or more than 50 slm, e.g., 18 slm, 31 slm, etc., and is not limited to this implementation.

In some embodiments, the flow rate for introduction of the second nitrogen source may be more than the flow rate for introduction of the first nitrogen source 220.

In some embodiments, the first nitrogen source 220 may be the same as the second nitrogen source.

In some embodiments, as for the step of “forming a second nitrided material layer 142”, the second nitrogen source may include ammonia gas (NH₃). In other implementations, other nitrogen element-containing compounds may also be used, e.g., nitrogen-containing gases, etc. The alternative ammonia gas is used as the second nitrogen source, which is not limited to this implementation.

In some implementations, as for the step of “forming a second nitrided material layer 142”, the thickness at which the second nitrided material layer 142 is deposited may be 30 nm to 40 nm, e.g., 30 nm, 34 nm, 38 nm, 40 nm, etc. In other implementations, the thickness at which the second nitrided material layer 142 is deposited may also be less than 30 nm, or more than 40 nm, e.g., 28 nm, 42 nm, etc., and is not limited to this implementation.

It is to be noted here that the semiconductor structure preparation process shown in the drawings and described in this specification are only a few examples of many preparation processes that can utilize the principle of the present disclosure. It shall be clearly understood that the principle of the present disclosure is by no means limited to any detail or any step of the semiconductor structure preparation process shown in the drawings or described in this specification.

Based on the above detailed description of an exemplary implementation of the semiconductor structure preparation process according to the present disclosure, an exemplary implementation of the semiconductor structure according to the present disclosure will be described below with reference to FIG. 4.

As shown in FIG. 4, in this implementation, the semiconductor structure according to the present disclosure includes the base 100. In particular, a metal material layer is arranged on the surface of the base 100, and the first nitrided material layer 141 and the second nitrided material layer 142 are sequentially arranged on the surface of the metal material layer. The first nitrided material layer 141 is formed through the chemical vapor deposition process and the second nitrided material layer 142 is formed through the plasma deposition process.

It is to be noted here that the semiconductor structure shown in the drawings and described in this specification are only a few examples of many semiconductor structures that can utilize the principle of the present disclosure. It shall be clearly understood that the principle of the present disclosure is by no means limited to any detail of the semiconductor structure shown in the drawings or described in this specification.

In conclusion, in the semiconductor structure preparation process according to the present disclosure, such a process design is employed that a nitride is deposited on the surface of the conductive layer using the chemical vapor deposition process and then deposited using the plasma deposition process. Nitrogen sources are not affected by plasmas during the chemical vapor deposition process and their activities are thus improved, as a result of which the conductive layer exposed can be prevented from being nitrided. Furthermore, according to the present disclosure, with the process design that the surface of the conductive layer of the base of the semiconductor structure is covered with a silicon-containing material layer before the nitride is deposited, the conductive layer exposed can be further prevented from being nitrided during the subsequent nitride deposition process, through use of the silicon-containing material layer covering the surface of the conductive layer. Therefore, the semiconductor structure preparation process according to the present disclosure can prevent the conductive layer from being nitrided, and the semiconductor structure prepared from this preparation process has excellent film resistance uniformity and higher product yields.

The exemplary implementations of the semiconductor structure preparation process and the semiconductor structure according to the present disclosure are described and/or illustrated in detail above. However, the implementations of the present disclosure are not limited to the specific implementations described herein. On the contrary, the components and/or steps of each implementation may be used independently and separately from other components and/or steps described herein. Each component and/or each step of one implementation may also be used in combination with other components and/or steps of other implementations. When the elements/components/etc. described and/or illustrated herein are introduced, the terms “one”, “a” and “the” are intended to mean that there exists one or more elements/components/etc. The terms “comprising”, “including” and “having” are intended to be inclusive and mean that there may be additional elements/components/etc. other than the listed elements/components/etc. In addition, the terms “first” and “second” in the claims and description are used only as marks, and are not numerical restrictions on their objects.

While the semiconductor structure preparation process and the semiconductor structure according to the present disclosure have been described in accordance with different specific embodiments, those skilled in the art will recognize that the implementation of the present disclosure can be modified within the spirit and scope of the claims.

What is claimed is:

1. A semiconductor structure preparation process, comprising the following steps of:
introducing a first silicon source, and forming a first silicon containing material layer by deposition on a surface of a base of a semiconductor structure;
introducing a first nitrogen source, and forming a first nitrided material layer by deposition on a surface of the first silicon containing material layer using a chemical vapor deposition process;
introducing a second silicon source, and forming a second silicon containing material layer by deposition on a surface of the first nitrided material layer; and
introducing a second nitrogen source, and forming a second nitrided material layer by deposition on a surface of the second silicon containing material layer using a plasma deposition process.

2. The semiconductor structure preparation process according to claim 1, wherein in the step of forming the first silicon containing material layer, the first silicon source is introduced in multiple cycles.

3. The semiconductor structure preparation process according to claim 2, wherein in the step of forming the first silicon containing material layer, a number of cycles for introduction of the first silicon source is 3 to 7.

4. The semiconductor structure preparation process according to claim 1, wherein the first silicon source comprises one of or a composition of at least two of dichlorosilane, trichlorosilane, and silane; and/or the second silicon source comprises one of or a composition of at least two of dichlorosilane, trichlorosilane, and silane.

5. The semiconductor structure preparation process according to claim 1, wherein the first nitrogen source is the same as the second nitrogen source, and the second nitrogen source has a flow rate greater than the first nitrogen source.

6. The semiconductor structure preparation process according to claim 5, wherein a flow rate for introduction of the first nitrogen source is 10 slm to 30 slm; and/or the flow rate for introduction of the second nitrogen source is 20 slm to 50 slm.

7. The semiconductor structure preparation process according to claim 5, wherein the first nitrogen source comprises ammonia gas and the second nitrogen source comprises ammonia gas.

8. The semiconductor structure preparation process according to claim 1, wherein the first nitrided material layer has a thickness of 3 nm to 15 nm.

9. The semiconductor structure preparation process according to claim 1, wherein the second nitrided material layer has a thickness of 30 nm to 40 nm.

10. A semiconductor structure, wherein the semiconductor structure comprises a base, a metal material layer is arranged on a surface of the base, a first nitrided material layer and a second nitrided material layer are sequentially arranged on a surface of the metal material layer, the first nitrided material layer is formed through a chemical vapor deposition process, and the second nitrided material layer is formed through a plasma deposition process.
